(19) United States
(12) Patent Application Publication
(10) Pub. No.: US 2026/0101549 A1
(43) Pub. Date: Apr. 9, 2026

(54) PLACEHOLDER FOR BACKSIDE CONTACT

(71) Applicant: International Business Machines Corporation, Armonk, NY (US)

(72) Inventors: Lijuan Zou, Albany, NY (US); Ruilong Xie, Niskayuna, NY (US); Tao Li, Slingerlands, NY (US); Fabio Carta, Pleasantville, NY (US); Erik Milosevic, Schenectady, NY (US); Kisik Choi, Watervliet, NY (US)

(21) Appl. No.: 18/910,315

(22) Filed: Oct. 9, 2024

(51) Int. Cl. H01L 29/06; H01L 29/417; H01L 29/423; H01L 29/66; H01L 29/775; H01L 29/786

(52) U.S. Cl. CPC H10D 62/116; H10D 30/6729; H10D 64/258; H10D 30/014; H10D 30/43; H10D 30/6735; H10D 30/6757; H10D 62/121

(57) ABSTRACT

Embodiments of present invention provide a semiconductor structure. The semiconductor structure includes a transistor having a first and a second source/drain (S/D) region; a backside contact in contact with a bottom surface of the first S/D region; and a placeholder underneath the second S/D region, where the placeholder includes a first portion and a second portion on top of the first portion; the first portion being embedded in a backside interlevel-dielectric (BILD) layer; the second portion being at least partially surrounded by a dielectric liner; and a top section of the second portion being above the top surface of the BILD layer and surrounded by an airgap.

### BACKGROUND

The present application relates to manufacturing of semiconductor integrated circuits. More particularly, it relates to forming placeholder for backside contact of transistor and the structure formed thereby.

As semiconductor industry moves towards smaller node, field-effect-transistors (FETs) are aggressively scaled to fit into reduced footprint or real estate with increased device density. In the meantime, some contacts to the transistors may be moved from the frontside to the backside of the transistors as well, known as backside contacts, as a mean to further enhance device density.

Generally, in order to form backside contacts, placeholders are usually first formed in the substrate during the frontside processing. The placeholders are then accessed from the backside of the substrate or device and replaced with backside contacts. In forming the placeholders, recesses are first formed in source/drain regions of transistors and openings are then made, through the recesses, in the substrate below the source/drain regions. However, with the ever shrinking gate-pitch such as when gate-pitch becomes less than 48 nm, the process of forming placeholders may be interfered or affected by other frontside processes. For example, openings created for the placeholders may be affected by pinch-off of liners.

### SUMMARY

Embodiments of present invention provide a semiconductor structure. The semiconductor structure includes a transistor having a first and a second source/drain (S/D) region; a backside contact in contact with a bottom surface of the first S/D region; and a placeholder underneath the second S/D region, where the placeholder includes a first portion and a second portion on top of the first portion; the first portion being embedded in a backside interlevel-dielectric (BILD) layer; the second portion being at least partially surrounded by a dielectric liner; and a top surface of the second portion being above a top surface of the BILD layer.

According to one embodiment, the second portion of the placeholder has an inverted trapezoidal shape with a wider base at top and a narrower base at bottom.

In one embodiment, a top section of the second portion of the placeholder is above the top surface of the BILD layer and is surrounded by an airgap, and a bottom section of the second portion of the placeholder is directly surrounded by the dielectric liner.

In another embodiment, a first portion of the backside contact directly contacts the first S/D region and is directly surrounded by the BILD layer.

According to another embodiment, the second portion of the placeholder is directly surrounded by the dielectric liner and a top section of the second portion of the placeholder is surrounded by a set of inner spacers via the dielectric liner.

According to yet another embodiment, the second portion of the placeholder has a top section in an inverted trapezoidal shape and a bottom section in a trapezoidal shape, both the top section and the bottom section being directly surrounded by the dielectric layer.

In one embodiment, the first portion of the placeholder and the bottom section of the second portion of the placeholder forms a diamond shape.

In one embodiment, the transistor is a nanosheet transistor having a set of nanosheets including a bottom-most nanosheet, and the top surface of the second portion of the placeholder is at or below the bottom-most nanosheet.

### BRIEF DESCRIPTION OF THE DRAWINGS

The present invention will be understood and appreciated more fully from the following detailed description of embodiments of present invention, taken in conjunction with accompanying drawings of which:

FIG. 1 to FIG. 15 are demonstrative illustrations of cross-sectional view of a semiconductor structure at various steps of manufacturing thereof according to one embodiment of present invention;

FIG. 16 to FIG. 24 are demonstrative illustrations of cross-sectional view of a semiconductor structure at various steps of manufacturing thereof according to another embodiment of present invention;

FIG. 25 to FIG. 35 are demonstrative illustrations of cross-sectional view of a semiconductor structure at various steps of manufacturing thereof according to yet another embodiment of present invention; and

FIG. 36 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

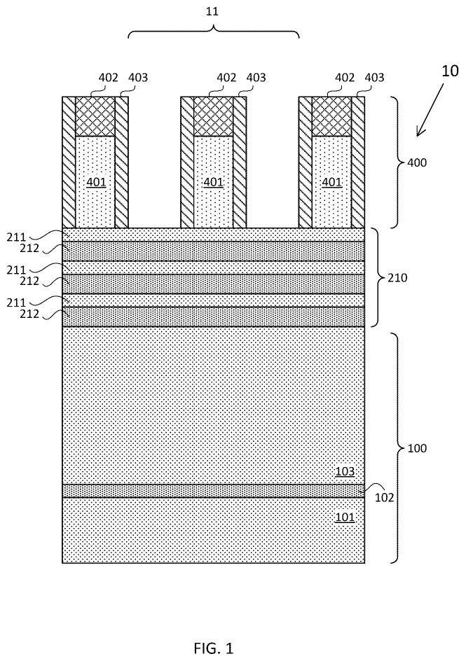

FIG. 1 is a demonstrative illustration of cross-sectional view of a semiconductor structure 10 in a step of manufacturing thereof according to one embodiment of present invention. As a non-limiting example, the semiconductor structure 10 may include a transistor such as a nanosheet (NS) transistor 11. FIG. 1 demonstratively illustrates a cross-sectional view of the NS transistor 11, at a step of manufacturing thereof, with a cross-section made along the length of gate of the NS transistor 11.

Embodiments of present invention provide receiving or providing a semiconductor substrate 100 and forming a stack of nanosheets 210 on top of the semiconductor substrate 100. The semiconductor substrate 100 may be a bulk silicon (Si) substrate, a bulk germanium (Ge) substrate, a silicon-germanium (SiGe) substrate, a silicon-on-insulator (SOI) substrate, a silicon-germanium-on-insulator (SGOI), and/or other suitable substrate. As is illustrated in FIG. 1, the semiconductor substrate 100 may be a SOI substrate that includes a bulk Si substrate 101, a dielectric layer 102 on top of the bulk Si substrate 101, and a Si layer 103 on top of the dielectric layer 102. During subsequent processes, the dielectric layer 102 may work or function as an etch-stop layer (ESL) and may thus be referred to as an ESL.

The stack of nanosheets 210 may include a set of Si nanosheets 211 stacked together, alternately, with a set of sacrificial layers 212. The set of sacrificial layers 212 may be a set of SiGe layers and may have an etch selectivity that is different from the set of Si nanosheets 211.

Embodiments of present invention further provide forming a set of sacrificial gate structures 400 on top of the stack of nanosheets 210. Each of the sacrificial gate structures 400 may include a sacrificial gate 401, a capping layer 402 on top of the sacrificial gate 401, and sidewall spacers 403 at sidewalls of the sacrificial gate 401 and the capping layer 402. The sacrificial gate 401 may include, for example, polysilicon (Poly-Si) in material, the capping layer 402 and sidewall spacers 403 may include dielectric material such as, for example, silicon-nitride (SiN), silicon-oxide (SiOx), and/or other suitable materials.

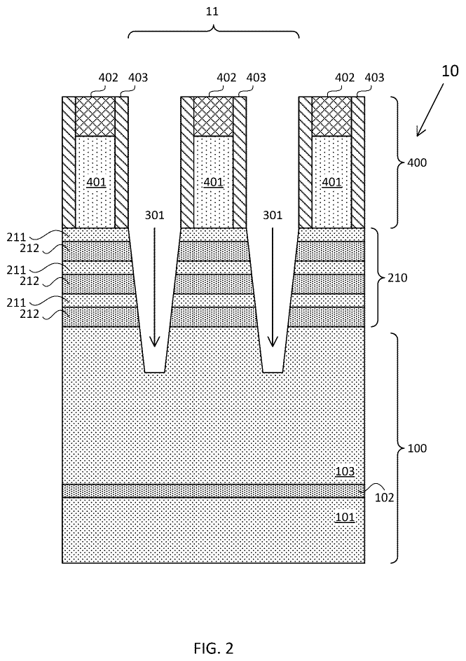

FIG. 2 is a demonstrative illustration of cross-sectional view of a semiconductor structure 10 in a step of manufacturing thereof, following the step illustrated in FIG. 1, according to one embodiment of present invention. More particularly, embodiments of present invention provide recessing the stack of nanosheets 210 in source/drain regions of the NS transistor 11, in a selective etch process using the sacrificial gate structures 400 as an etch mask. The recessing may create recesses 301 in the stack of nanosheets 210, thereby truncating the stack of nanosheets 210 into multiple stacks of nanosheets 210. The recesses 301 may also extend into the Si layer 103 of substrate 100. By the nature of etch process, the recesses 301 may have slanted sidewalls that lead to a narrowed width at bottoms of the recesses 301.

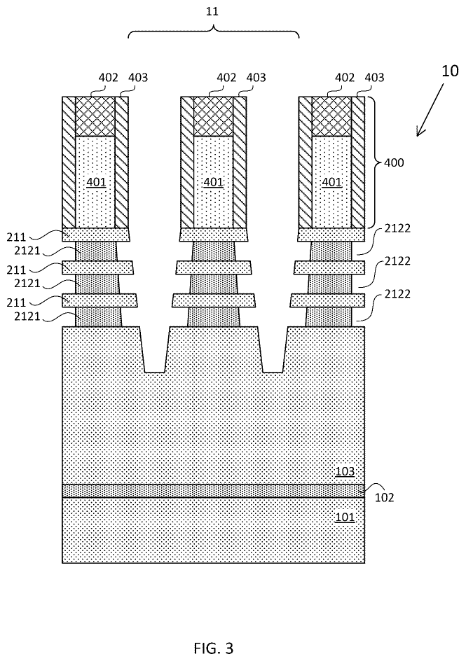

FIG. 3 is a demonstrative illustration of cross-sectional view of a semiconductor structure 10 in a step of manufacturing thereof, following the step illustrated in FIG. 2, according to one embodiment of present invention. More particularly, embodiments of present invention provide performing an indentation process of recessing the set of sacrificial layers 212, from exposed sidewalls thereof, in a selective etch process relative to the set of Si nanosheets 211. For example, the indentation process may strategically apply etch selectivity between the Si nanosheets 211 and the sacrificial layers 212 of SiGe to selectively remove portions of the sacrificial layers 212 at the ends thereof. The indentation process may thus create a set of sacrificial sheets 2121 with a plurality of indents 2122 at ends of the set of sacrificial sheets 2121.

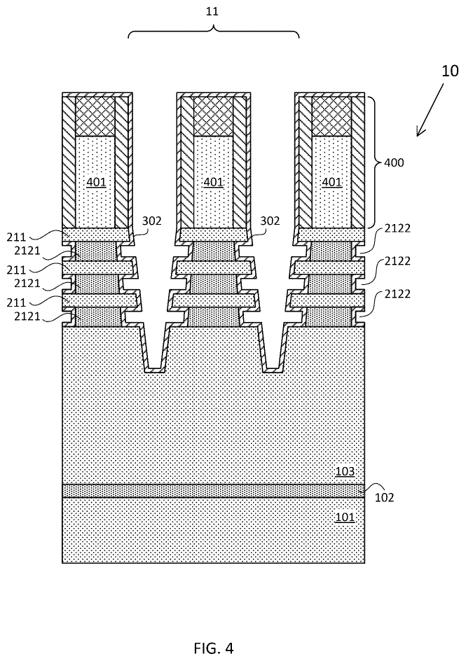

FIG. 4 is a demonstrative illustration of cross-sectional view of a semiconductor structure 10 in a step of manufacturing thereof, following the step illustrated in FIG. 3, according to one embodiment of present invention. More particularly, embodiments of present invention provide forming a conformal dielectric layer 302 that lines the recesses 301 in the S/D regions of the NS transistor 11. The conformal dielectric layer 302, which may be referred to as a dielectric liner as well, may be formed through a deposition process such as, for example, a chemical-vapor-deposition (CVD) process, a physical-vapor-deposition (PVD) process, an atomic-layer-deposition (ALD) process, or other suitable deposition process. The conformal dielectric layer 302 may conformally cover sidewalls of the set of Si nanosheets 211; partially fill the indents 2122 at the ends of the sacrificial sheets 2121; and cover the openings in the Si layer 103 below the recesses 301.

The conformal dielectric layer 302 may be formed to have a thickness that is thin enough, thereby not causing pinch-off in the openings in the Si layer 103. For example, the thickness of the conformal dielectric layer 302 may range from about 2.5 nm to about 3.5 nm and may be less than half of a thickness of the sacrificial sheets 2121 such that the conformal dielectric layer 302 may not pinch off in the indents 2122 either. In one embodiment, the conformal dielectric layer 302 may include or be made of SiN, SiOx, or other suitable dielectric materials. Such other suitable dielectric materials may include, for example, silicon-carbide (SiC), silicoboron-carbonitride (SiBCN), silicon-oxycarbonitride (SiOCN), or silicon-oxycarbide (SiOC).

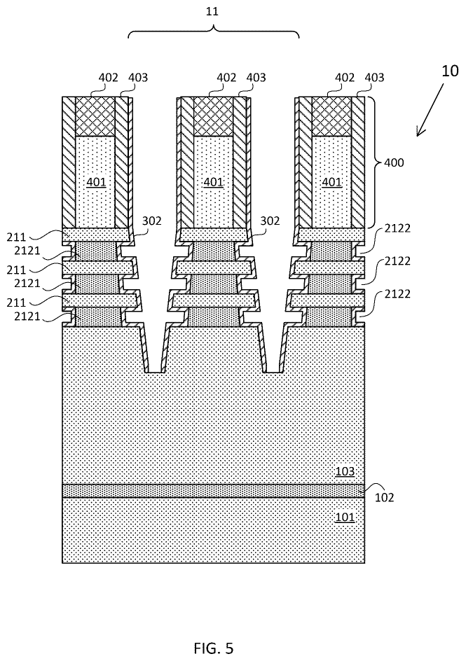

FIG. 5 is a demonstrative illustration of cross-sectional view of a semiconductor structure 10 in a step of manufacturing thereof, following the step illustrated in FIG. 4, according to one embodiment of present invention. More particularly, embodiments of present invention provide performing an anisotropic and/or directional etch process such as, for example, a reactive-ion-etch (RIE) process to remove horizontal portions of the conformal dielectric layer 302. For example, the RIE process may remove a portion of the conformal dielectric layer 302 at the bottom of the openings in the Si layer 103 such that the Si layer 103 may be exposed for further processing. The RIE process may also remove portions of the conformal dielectric layer 302 that cover the capping layer 402 and tops of the sidewall spacers 403 of the sacrificial gate structures 400.

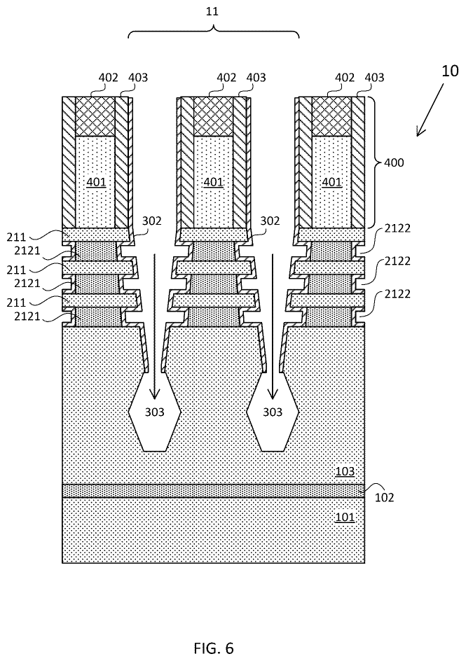

FIG. 6 is a demonstrative illustration of cross-sectional view of a semiconductor structure 10 in a step of manufacturing thereof, following the step illustrated in FIG. 5, according to one embodiment of present invention. More particularly, embodiments of present invention provide selectively etching the Si layer 103 exposed below the recesses 301, not covered by the conformal dielectric layer 302, to create cavities 303 in the Si layer 103. The cavities 303 created through this etch process, such as through a selective RIE process, may be in diamond shape, at least cross-sectionally. The cavities 303 may later be filled with epitaxial materials to form placeholders. In the meantime, the etch process may leave the conformal dielectric layer 302 substantially unetched, which protects the Si nanosheets 211 that will be used later to form channel regions of the NS transistor 11.

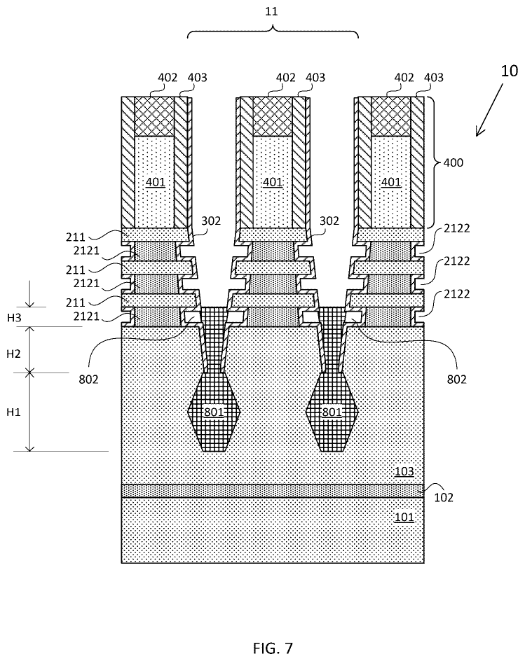

FIG. 7 is a demonstrative illustration of cross-sectional view of a semiconductor structure 10 in a step of manufacturing thereof, following the step illustrated in FIG. 6, according to one embodiment of present invention. More particularly, embodiments of present invention provide epitaxially growing placeholders 801 in the cavities 303, in the openings in the Si layer 103 above the cavities 303, and in part of the recesses 301. For example, silicon-germanium (SiGe) may be epitaxially grown from the Si material of the Si layer 103 at sidewalls of the cavities 303. The epitaxial SiGe may continue to grow in the openings surrounded by the conformal dielectric layer 302 and grow to a level above a top surface of the Si layer 103. As a result, the placeholders 801 may be formed to have a top surface that is at or below a bottom-most Si nanosheet of the set of Si nanosheets 211. By being at the bottom-most Si nanosheet, one or more airgaps 802 may be created, between the bottom-most Si nanosheet and the Si layer 103. The one or more airgaps 802 may be in areas of the one or more indents 2122, being surrounded by the conformal dielectric layer 302, which lines the indents 2122, and the placeholders 801.

As is illustrated in FIG. 7, the placeholders 801 may have a first portion and a second portion on top of the first portion. The first portion of the placeholders 801 may have a height H1 and have a diamond shape with multi-facets. The second portion may have an inverted trapezoidal shape with a wider base at top and a narrower base at bottom. Th second section may further include a bottom section with a height H2 and a top section, on top of the bottom section, with a height H3. The bottom section of the second portion of the placeholders 801 may be directly surrounded by the conformal dielectric layer 302. The top section of the second portion of the placeholder 801 may be directly surrounded by airgaps 802. The airgaps 802 may be formed in one or more bottom-most indents 2122, surrounded by the conformal dielectric layer 302 and the placeholders 801.

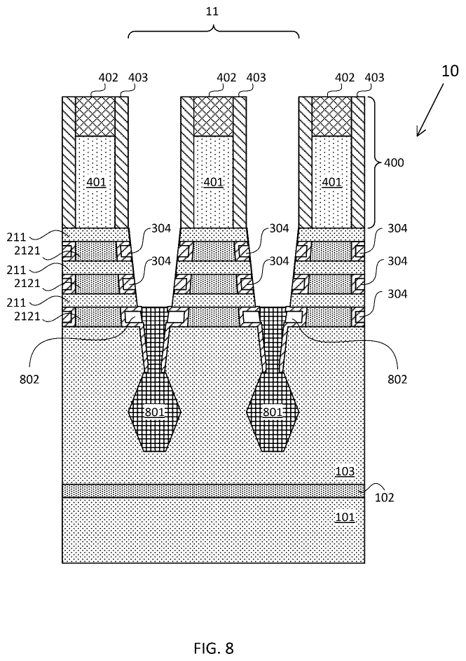

FIG. 8 is a demonstrative illustration of cross-sectional view of a semiconductor structure 10 in a step of manufacturing thereof, following the step illustrated in FIG. 7, according to one embodiment of present invention. More particularly, embodiments of present invention provide forming additional conformal dielectric layer, in the recesses 301, on top of and lining the conformal dielectric layer 302. This additional conformal dielectric layer may pinch off in, thereby completely fill, the remaining portions of the indents 2122. Next, an isotropic etch process, such as a wet etch process using hot phosphorus, may be applied to remove portions of this additional conformal dielectric layer and the conformal dielectric layer 302 underneath thereof that are both outside the indents 2122. This isotropic etch process may thus leave only portions of the conformal dielectric layer 302 and the additional conformal dielectric layer inside the indents 2122 thereby forming one or more inner spacers 304. This isotropic etch process may also expose end surfaces, or sidewalls, of the set of Si nanosheets 211 for further processing.

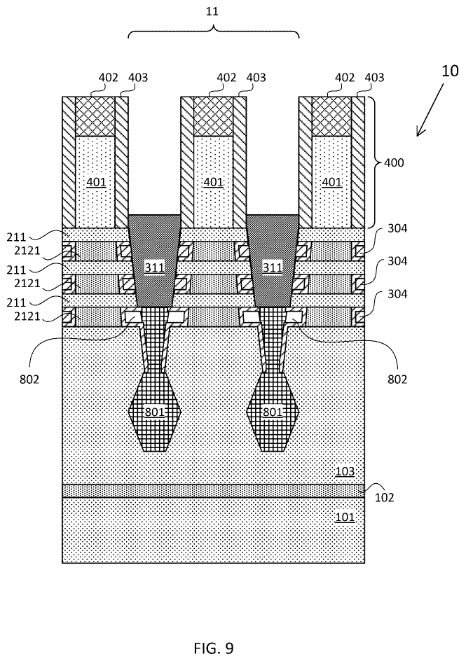

FIG. 9 is a demonstrative illustration of cross-sectional view of a semiconductor structure 10 in a step of manufacturing thereof, following the step illustrated in FIG. 8, according to one embodiment of present invention. More particularly, embodiments of present invention provide forming source/drain (S/D) regions 311 of the NS transistor 11 by epitaxially growing P+ Epi SiGe:B or N+ Epi Si:P from exposed end surfaces of the Si nanosheets 211, depending on the type of the NS transistor 11 to be formed. Following the shape of the recesses 301, the S/D regions 311 of the NS transistor 11 may have slanted sidewalls to have a wider width at the top and narrower width at the bottom.

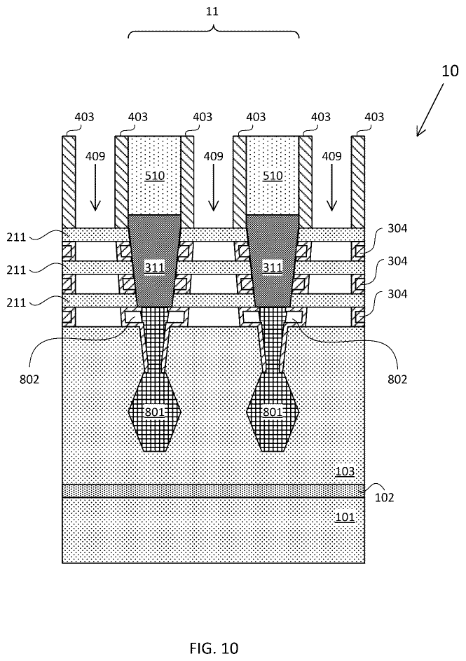

FIG. 10 is a demonstrative illustration of cross-sectional view of a semiconductor structure 10 in a step of manufacturing thereof, following the step illustrated in FIG. 9, according to one embodiment of present invention. More particularly, embodiments of present invention provide performing a replacement-metal-gate (RMG) process to form a metal gate of the NS transistor 11. In doing so, embodiments of present invention provide first covering the S/D regions 311 with a dielectric material thereby forming a dielectric layer 510 on top of the S/D regions 311. Next, the capping layer 402 of the sacrificial gate structures 400 may be removed, for example through a chemical-mechanical-polishing (CMP) process or a reactive ion etch (RIE) process, to expose the sacrificial gates 401, and remove the exposed sacrificial gates 401 in a selective etch process to create openings 409. After removing the sacrificial gates 401, embodiments of present invention provide removing, through the openings 409 in a selective etch process, the set of sacrificial sheets 2121 to expose a central portion of the set of Si nanosheets 211, while end portions of the set of Si nanosheets 211 may be covered or wrapped around by the sidewall spacers 403 and/or the inner spacers 304.

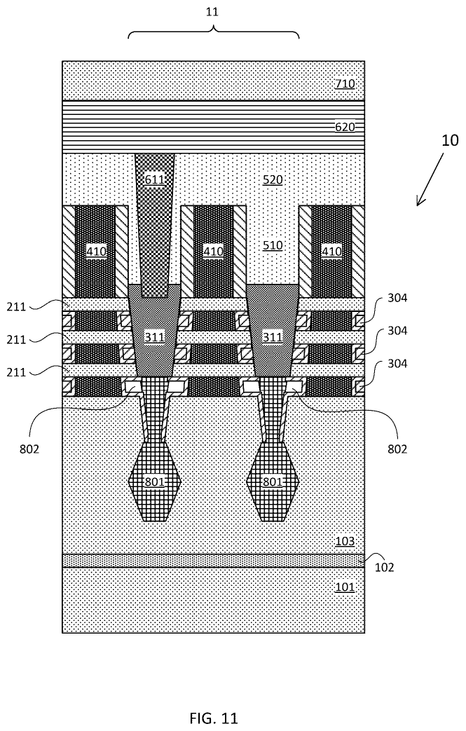

FIG. 11 is a demonstrative illustration of cross-sectional view of a semiconductor structure 10 in a step of manufacturing thereof, following the step illustrated in FIG. 10, according to one embodiment of present invention. More particularly, embodiments of present invention provide depositing a gate dielectric layer, through the openings 409, surrounding the central portions of the set of Si nanosheets 211, depositing one or more work-function metal (WFM) layers on top of the gate dielectric layer, and depositing a conductive material on top of the one or more WFM layers thereby forming a set of metal gates 410. Subsequently, a CMP process may be applied to planarize a top surface of the set of metal gates 410 to be co-planar with the top surface of the dielectric layer 510. Next, additional dielectric materials such as a dielectric layer 520 may be formed through deposition on top of the set of metal gate 410 and the dielectric layer 510; one or more frontside source/drain (S/D) contacts such as a frontside S/D contact 611 may be formed to be in contact with the S/D region 311; and a back-end-of-line (BEOL) interconnect structure 620 may be formed on top of the dielectric layer 520. The BEOL interconnect structure 620 may provide signal routing, power supply, and other interconnect functions to the transistors such as the NS transistor 11 through the one or more frontside S/D contact.

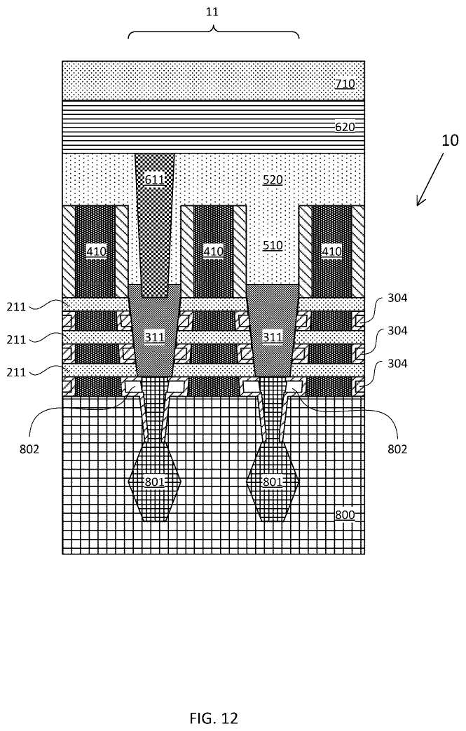

After forming the BEOL interconnect structure 620, a handling wafer 710 may be attached, for example through a bonding process, to the BEOL interconnect structure 620 such as the semiconductor structure 10 may be flipped upside-down for processing from the backside of the semiconductor substrate 100. Hereinafter, although various processes may be applied from the backside of the semiconductor structure 10, for the ease of illustration, FIGS. 12-15 will still be demonstratively illustrated upside-up and described according to that illustration.

FIG. 12 is a demonstrative illustration of cross-sectional view of a semiconductor structure 10 in a step of manufacturing thereof, following the step illustrated in FIG. 11, according to one embodiment of present invention. More particularly, embodiments of present invention provide removing the bulk Si substrate 101 through, for example, a CMP process, a grinding process, and/or other selective etch processes to stop at the dielectric layer 102; removing the dielectric layer 102 selectively to expose the Si layer 103; and removing the Si layer 103. The Si layer 103 may be selectively removed to expose the placeholders 801 which are made of a material, such as SiGe, different from that of the Si layer 103. Next, a backside interlevel-dielectric (BILD) layer 800 may be deposited, for example through a CVD process, a PVD process, and/or an ALD process, to cover the placeholders 801 such that the placeholders 801 may become embedded in the BILD layer 800.

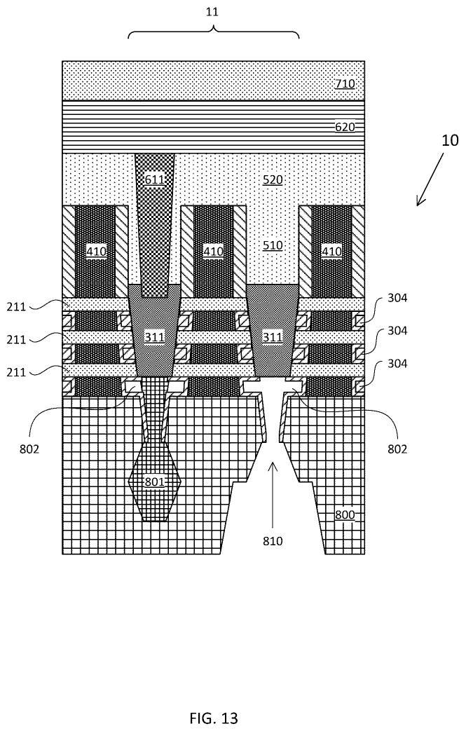

FIG. 13 is a demonstrative illustration of cross-sectional view of a semiconductor structure 10 in a step of manufacturing thereof, following the step illustrated in FIG. 12, according to one embodiment of present invention. More particularly, embodiments of present invention provide creating an opening 810 in the BILD layer 800, through a lithographic patterning process, to expose one of the placeholders 801 such as the placeholder 801 underneath a first S/D region of the NS transistor 11. Subsequently, the exposed placeholders 801 may be removed through a selective etch process. More specifically, the selective etch process may remove the first portion of the placeholder 801 that is in the diamond shape; remove the bottom section of the second portion of the placeholder 801 that is directly surrounded by the conformal dielectric layer 302; and remove the top section of the second portion of the placeholder 801, above a level of the BILD layer 800, to expose a bottom surface of the S/D region 311. The removal of the upper section of the second portion of the placeholder 801 may also expose or open up the airgaps 802 in the indents 2122 below the set of Si nanosheets 211, particularly below a bottom-most Si nanosheet of the set of Si nanosheets 211.

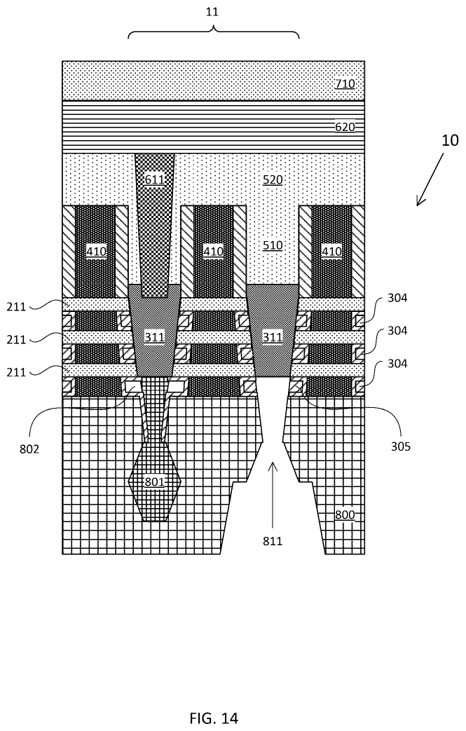

FIG. 14 is a demonstrative illustration of cross-sectional view of a semiconductor structure 10 in a step of manufacturing thereof, following the step illustrated in FIG. 13, according to one embodiment of present invention. More particularly, embodiments of present invention provide forming an additional conformal dielectric layer lining the opening 810 including the airgaps 802. This additional conformal dielectric layer may pinch off inside the airgaps 802 to completely fill the remaining portions of the indents 2122 below the bottom-most Si nanosheet 211. An isotropic etch process may subsequently be applied to remove most of the additional conformal dielectric layer outside the indents 2122, leaving only a portion thereof to remain inside the indents 2122 to form, together with the conformal dielectric layer 302, inner spacers 305. The removal of the conformal dielectric layer 302 outside the indents 2122 creates an opening 811.

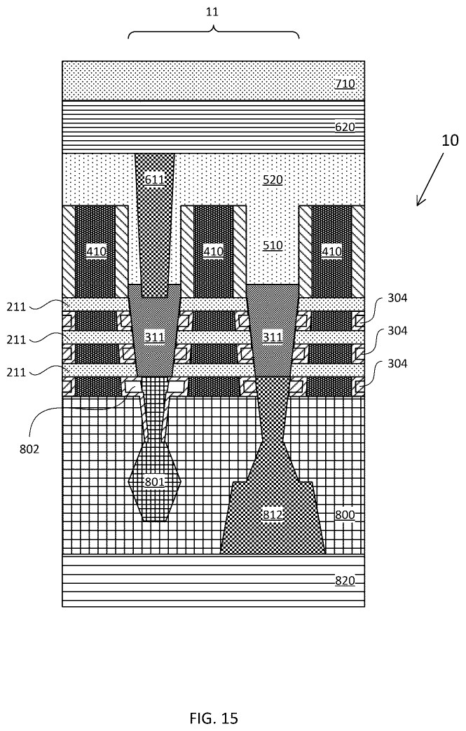

FIG. 15 is a demonstrative illustration of cross-sectional view of a semiconductor structure 10 in a step of manufacturing thereof, following the step illustrated in FIG. 14, according to one embodiment of present invention. More particularly, embodiments of present invention provide filling the opening 811 with a conductive material to form a backside contact 812 contacting the S/D region 311 of the NS transistor 11. As is illustrated in FIG. 15, a top section of the backside contact 812 that contacts the S/D region 311 may be surrounded by the inner spacers 305. A CMP process may be applied to planarize a bottom surface of the backside contact 812 such that it becomes co-planar with a bottom surface of the BILD layer 800.

After forming the backside contact 812, embodiments of present invention provide forming a backside BEOL structure 820 next to the BILD layer 800 and the backside contact 812. The backside BEOL structure 820 provides signal routing and/or power supply functions to various transistors such as the NS transistor 11.

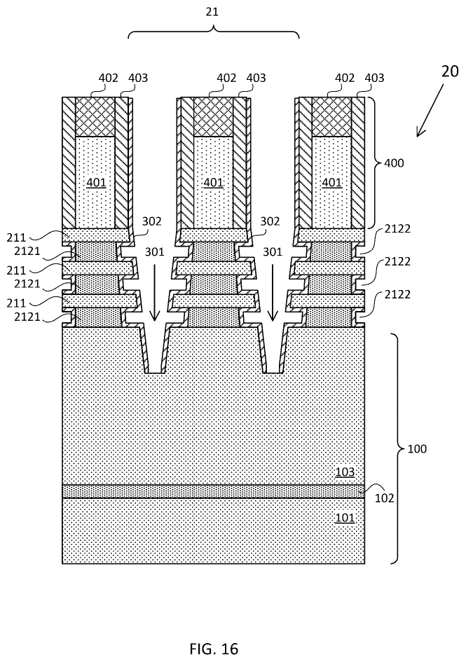

FIG. 16 to FIG. 24 are demonstrative illustrations of cross-sectional view of a semiconductor structure at various steps of manufacturing thereof according to another embodiment of present invention.

FIG. 16 is a demonstrative illustration of cross-sectional view of a semiconductor structure 20 in a step of manufacturing thereof according to one embodiment of present invention. More particularly, embodiments of present invention provide receiving, providing, or forming a semiconductor structure as is demonstratively illustrated in FIG. 4. Next, as is illustrated in FIG. 16, embodiments of present invention provide forming a semiconductor structure 20, including a NS transistor 21, by performing an anisotropic and/or directional etch process on the semiconductor structure illustrated in FIG. 4. The etch process may be, for example, a RIE process and may remove horizontal portions of the conformal dielectric layer 302 such as a portion of the conformal dielectric layer 302 in the openings in the Si layer 103 below the recesses 301. The RIE process may widen, to certain extent, the openings at the bottom of the recesses 301, which help mitigate pinch-off in a next deposition process of a conformal dielectric layer. In the meantime, the RIE process may also remove portions of the conformal dielectric layer 302 that cover the capping layer 402 and tops of the sidewall spacers 403 of the sacrificial gate structures 400.

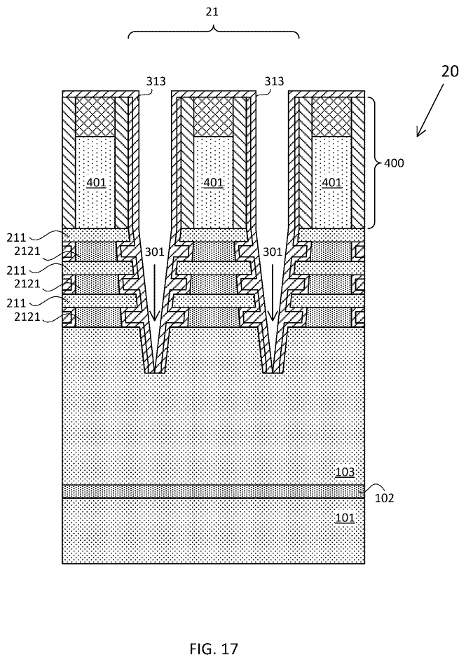

FIG. 17 is a demonstrative illustration of cross-sectional view of a semiconductor structure 20 in a step of manufacturing thereof, following the step illustrated in FIG. 16, according to one embodiment of present invention. More particularly, embodiments of present invention provide forming another conformal dielectric layer 313 on top of and lining the conformal dielectric layer 302. This conformal dielectric layer 313 may pinch off in, thereby completely fill, the remaining portions of the indents 2122. On the other hand, the widened openings in the Si layer 103 below the recesses 301 help prevent pinch-off from happening, which may be otherwise possible due to deposition of the conformal dielectric layer 313.

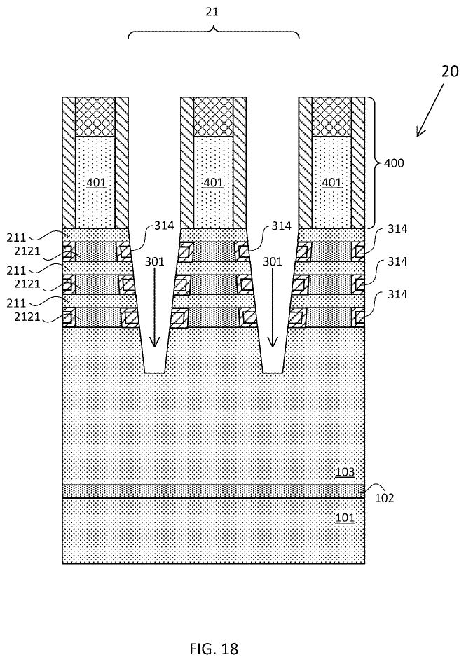

FIG. 18 is a demonstrative illustration of cross-sectional view of a semiconductor structure 20 in a step of manufacturing thereof, following the step illustrated in FIG. 17, according to one embodiment of present invention. More particularly, embodiments of present invention provide applying an isotropic etch process, such as a wet etch process using hot phosphorus, to remove portions of the conformal dielectric layer 313, and portions of the conformal dielectric layer 302 underneath thereof, leaving only pinched off portions of the conformal dielectric layer 313 and the conformal dielectric layer 302 underneath thereof in the one or more indents 2122 to form one or more inner spacers 314. In the meantime, since the conformal dielectric layer 313 is un-pinched at the bottom of the recesses 301, the conformal dielectric layer 313 and the conformal dielectric layer 302 underneath thereof may be completely removed, thereby exposing the Si layer 103 for further processing.

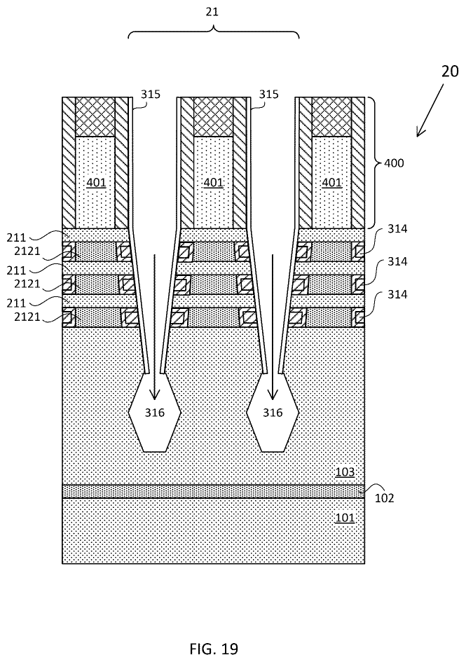

FIG. 19 is a demonstrative illustration of cross-sectional view of a semiconductor structure 20 in a step of manufacturing thereof, following the step illustrated in FIG. 18, according to one embodiment of present invention. More particularly, embodiments of present invention provide forming a conformal dielectric layer 315 as a protective dielectric liner covering sidewalls of the recesses 301 and the openings underneath thereof in the Si layer 103. Horizontal portions of the conformal dielectric layer 315 may subsequently be removed below the recesses 301 to expose the underneath Si layer 103. Next, embodiments of present invention provide performing, for example, a RIE process to create cavities 316 in the Si layer 103 directly below the recesses 301. The cavities 316 created through this RIE process may be in diamond shape, which may later be filled with materials, such as epitaxial SiGe, to form placeholders. The RIE process may be selective to the conformal dielectric layer 315, which works as a protective liner protecting sidewalls of the recesses 301 such as protecting the set of Si nanosheets 211 and the inner spacers 314 from the RIE process.

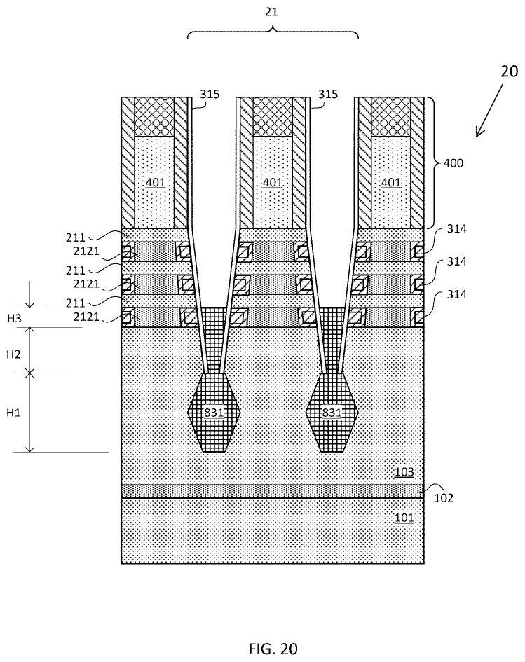

FIG. 20 is a demonstrative illustration of cross-sectional view of a semiconductor structure 20 in a step of manufacturing thereof, following the step illustrated in FIG. 19, according to one embodiment of present invention. More particularly, embodiments of present invention provide epitaxially growing placeholders 831 in the cavities 316, in the openings above the cavities 316 in the Si layer 103, and in part of the recesses 301. For example, SiGe may be epitaxially grown from the Si material of the Si layer 103 at sidewalls of the cavities 316. The epitaxial SiGe may continue to grow in the openings surrounded by the conformal dielectric layer 315. The placeholders 831 may be grown to have a top surface that is at or above a top surface of the Si layer 103, but at or below a bottom-most Si nanosheet of the set of Si nanosheets 211.

As is illustrated in FIG. 20, the placeholders 831 may have a first portion and a second portion on top of the first portion. The first portion of the placeholders 831 may have a height H1 and have a diamond shape with multi-facets. The second portion may have an inverted trapezoidal shape with a wider base at top and a narrower base at bottom. Th second section may further include a bottom section with a height H2 and a top section, on top of the bottom section, with a height H3. Both the bottom section and the top section of the second portion of the placeholders 831 may be directly surrounded by the conformal dielectric layer 302. The top section of the second portion of the placeholder 831 may be additionally surrounded by a set of inner spacers 314.

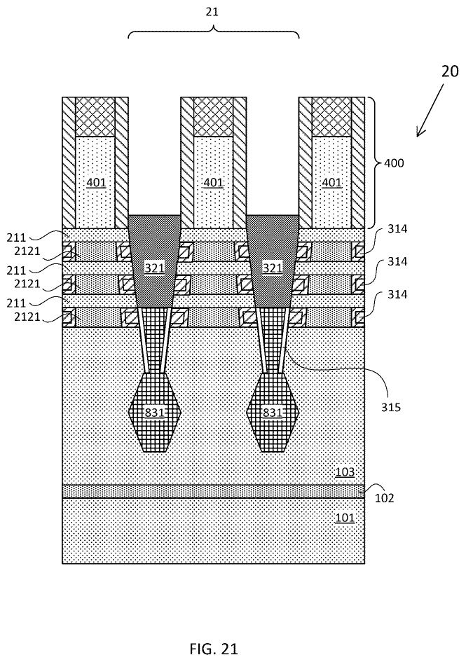

FIG. 21 is a demonstrative illustration of cross-sectional view of a semiconductor structure 20 in a step of manufacturing thereof, following the step illustrated in FIG. 20, according to one embodiment of present invention. More particularly, embodiments of present invention provide applying an isotropic etch process to remove portions of the conformal dielectric layer 315 which worked as a protective dielectric liner, above the placeholders 831, thereby exposing end surfaces of the set of Si nanosheets 211. Next, embodiments of present invention provide forming S/D regions 321 of the NS transistor 21 by epitaxially growing P+ Epi SiGe:B or N+ Epi Si:P from the exposed end surfaces of the set of Si nanosheets 211, depending on the type of NS transistor 21 to be formed. Following the shape of the recesses 301, the S/D regions 321 of the NS transistor 21 may have slanted sidewalls and have a wider width at the top and narrower width at the bottom.

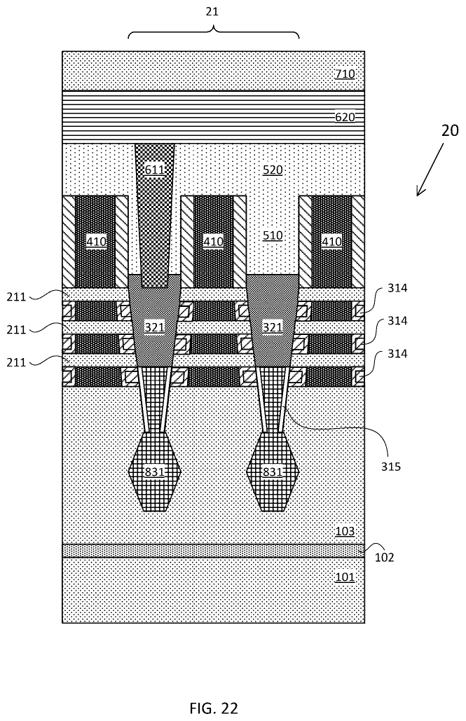

FIG. 22 is a demonstrative illustration of cross-sectional view of a semiconductor structure 20 in a step of manufacturing thereof, following the step illustrated in FIG. 21, according to one embodiment of present invention. More particularly, embodiments of present invention provide performing a RMG process to form a metal gate of the NS transistor 21. In doing so, embodiments of present invention provide first covering the S/D regions 321 with a dielectric material thereby forming a dielectric layer 510 on top of the S/D regions 321. Next, the capping layer 402 of the sacrificial gate structures 400 may be removed, for example through a CMP process or a RIE process, to expose the sacrificial gates 401, and remove the exposed sacrificial gates 401 and subsequently the set of sacrificial sheets 2121 to expose a central portion of the set of Si nanosheets 211.

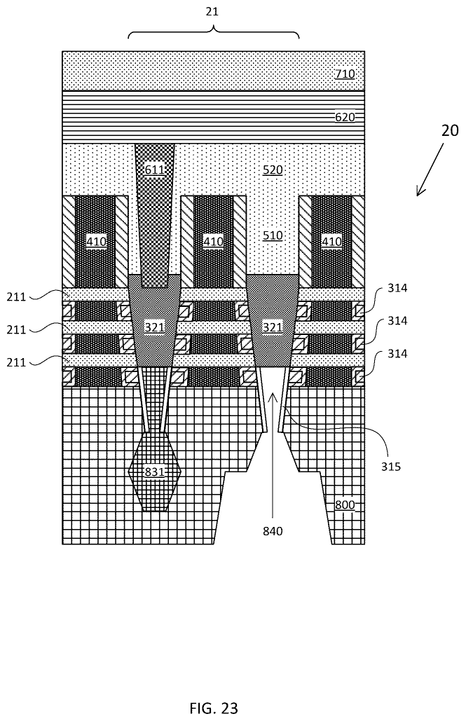

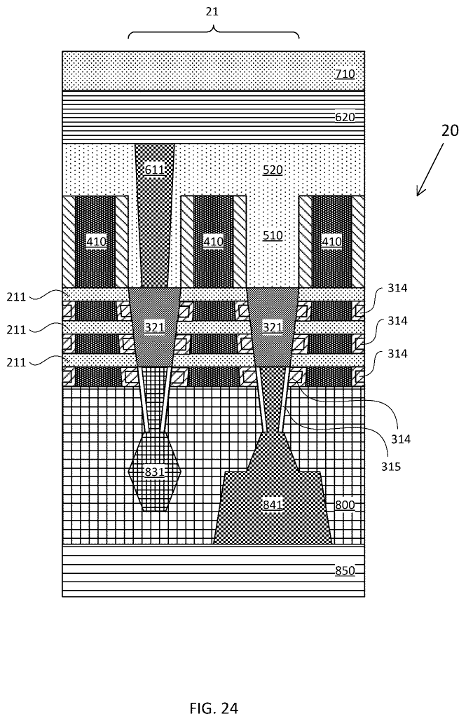

Next, embodiments of present invention provide depositing a gate dielectric layer surrounding the central portions of the set of Si nanosheets 211, depositing one or more WFM layers on top of the gate dielectric layer, and depositing a conductive material on top of the one or more WFM layers thereby forming a set of metal gates 410. A CMP process may be applied to planarize a top surface of the set of metal gates 410 to be co-planar with the top surface of the dielectric layer 510. Next, additional dielectric materials such as a dielectric layer 520 may be formed, for example through deposition, on top of the set of metal gate 410 and on top of the dielectric layer 510. Next, one or more frontside S/D contacts such as a frontside S/D contact 611 may be formed to be in contact with the S/D region 321; and a BEOL interconnect structure 620 may be formed on top of the dielectric layer 520. After forming the BEOL interconnect structure 620, a handling wafer 710 may be attached, for example through a bonding process, to the BEOL interconnect structure 620 such as the semiconductor structure 20 may be flipped upside-down for processing from the backside of the semiconductor substrate 100. Hereinafter, although various processes may be applied from the backside of the semiconductor structure 20, for the ease of illustration, FIGS. 23-24 will still be demonstratively illustrated upside-up and described according to that illustration.

FIG. 23 is a demonstrative illustration of cross-sectional view of a semiconductor structure 20 in a step of manufacturing thereof, following the step illustrated in FIG. 22, according to one embodiment of present invention. More particularly, embodiments of present invention provide removing the bulk Si substrate 101; removing the dielectric layer 102 selectively to expose the Si layer 103; and removing the Si layer 103 to expose the placeholders 831. Next, a BILD layer 800 may be deposited to cover the placeholders 831 such that the placeholders 831 may become embedded in the BILD layer 800.

Next, embodiments of present invention provide creating an opening 840 in the BILD layer 800, through a lithographic patterning process, to expose one of the placeholders 831 such as the placeholder 831 underneath a first S/D region 321 of the NS transistor 21. Next, the exposed placeholders 831 may be removed through a selective etch process. The selective etch process may remove the placeholder 831, selective to the conformal dielectric layer 315, to expose a bottom surface of the S/D region 321.

FIG. 24 is a demonstrative illustration of cross-sectional view of a semiconductor structure 20 in a step of manufacturing thereof, following the step illustrated in FIG. 23, according to one embodiment of present invention. More particularly, embodiments of present invention provide filling the opening 840 with a conductive material to form a backside contact 841 contacting the S/D region 321 of the NS transistor 21. As is illustrated in FIG. 24, an upper section of the backside contact 841 may be surrounded by both the conformal dielectric layer 315 and a set of inner spacers 314. Next, a CMP process may be applied to planarize a bottom surface of the backside contact 841 to be co-planar with a bottom surface of the BILD layer 800. Subsequently, a backside BEOL structure 850 may be formed next to the BILD layer 800 and the backside contact 841 to provide signal routing and/or power supply functions to the transistors such as the NS transistor 21.

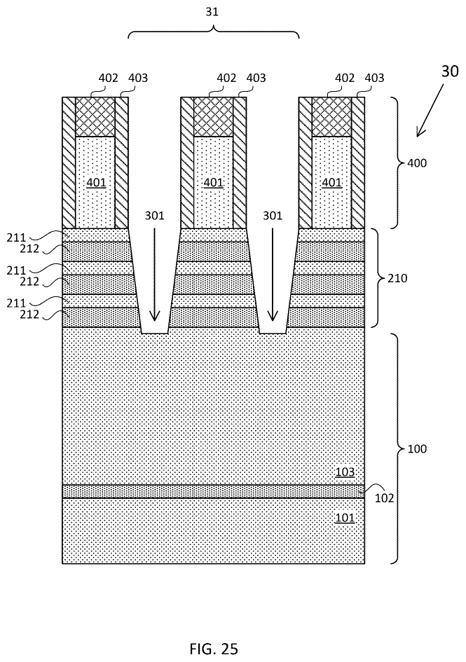

FIG. 25 to FIG. 35 are demonstrative illustrations of cross-sectional view of a semiconductor structure at various steps of manufacturing thereof according to another embodiment of present invention.

FIG. 25 is a demonstrative illustration of cross-sectional view of a semiconductor structure 30 in a step of manufacturing thereof according to one embodiment of present invention. More particularly, embodiments of present invention provide receiving, providing, or forming a semiconductor structure as is demonstratively illustrated in FIG. 1. Next, as is illustrated in FIG. 25, embodiments of present invention provide forming a semiconductor structure 30, including a NS transistor 31, by recessing the stack of nanosheets 210 in source/drain regions of the NS transistor 31. The recessing may be performed in a selective etch process using the sacrificial gate structures 400 as an etch mask. The recessing may create recesses 301 in the stack of nanosheets 210, thereby truncating the stack of nanosheets 210 into multiple stacks of nanosheets 210. The recesses 301 may slightly extend into the Si layer 103 of substrate 100.

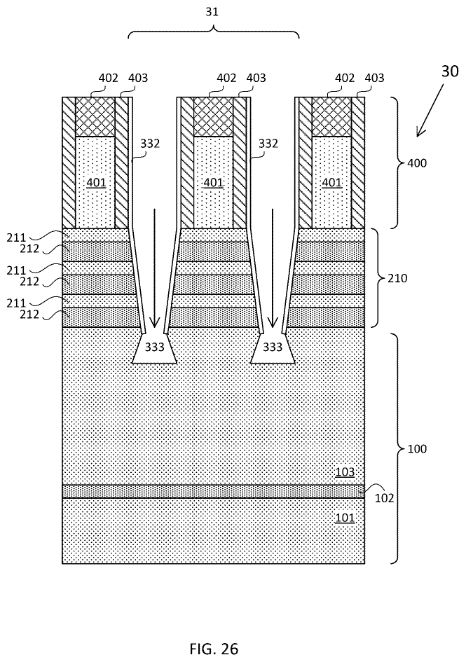

FIG. 26 is a demonstrative illustration of cross-sectional view of a semiconductor structure 30 in a step of manufacturing thereof, following the step illustrated in FIG. 25, according to one embodiment of present invention. More particularly, embodiments of present invention provide covering sidewalls of the recesses 301 with a protective liner 332 and notching the bottom of the recesses 301 to create openings 333 in the Si layer 103 with increased bottom CD (critical dimension) or horizontal width. For example, in one embodiment, the protective liner 332 may be a layer of polymer and the notching may be performed through a RIE process whose condition may be tuned to cause more etching deep into the Si layer 103. The widening of the bottom of the recesses 301 and the resulting openings 333 help prevent pinch-off when later a conformal dielectric layer is used to form inner spacers, as being described below in more details.

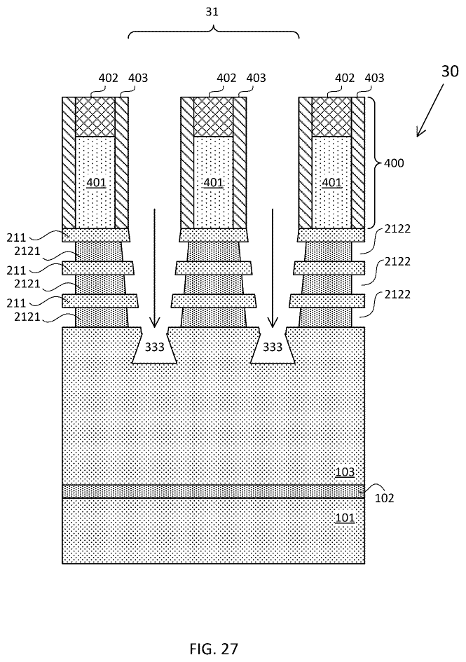

FIG. 27 is a demonstrative illustration of cross-sectional view of a semiconductor structure 30 in a step of manufacturing thereof, following the step illustrated in FIG. 26, according to one embodiment of present invention. More particularly, embodiments of present invention provide selectively removing the protective liner 332 to expose the set of sacrificial layers 212 and performing an indentation process to recess the set of sacrificial layers 212, from exposed sidewalls thereof, in a selective etch process relative to the set of Si nanosheets 211. The indentation process may thus create a set of sacrificial sheets 2121 with a plurality of indents 2122 at ends of the sacrificial sheets 2121.

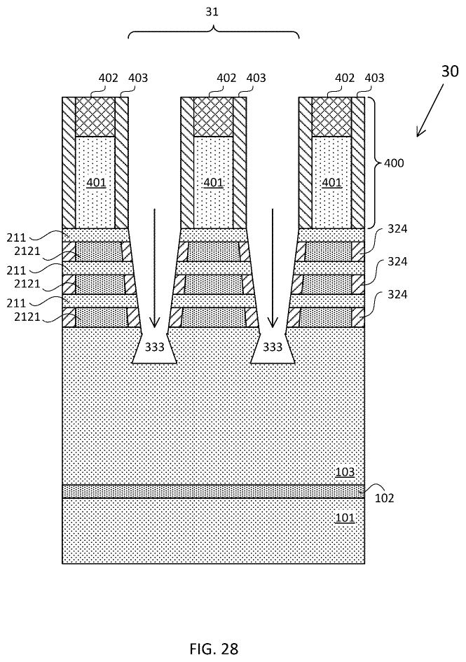

FIG. 28 is a demonstrative illustration of cross-sectional view of a semiconductor structure 30 in a step of manufacturing thereof, following the step illustrated in FIG. 27, according to one embodiment of present invention. More particularly, embodiments of present invention provide forming a conformal dielectric layer that lines the recesses 301 in the S/D regions of the NS transistor 31. The conformal dielectric layer may be deposited to completely fill, through pinch-off, the indents 2122 at the ends of the sacrificial sheets 2121 and may fill the openings 333, but only partially because of the widened width of the openings 333. Next, an isotropic etch process, such as a wet etch process based on hot phosphorus, may be applied to remove portions of the conformal dielectric layer outside the indents 2122, leaving only portions thereof inside the indents 2122 to form one or more inner spacers 324. In the meantime, since the conformal dielectric layer does not pinch off inside the openings 333, they may be selectively removed through the isotropic etch process to expose or re-expose the underneath Si layer 103.

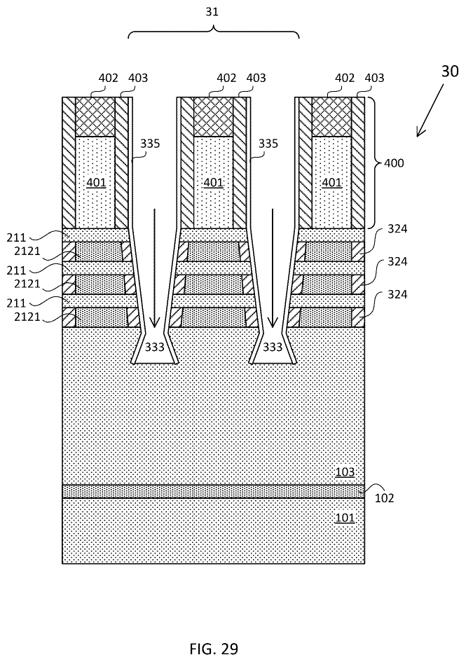

FIG. 29 is a demonstrative illustration of cross-sectional view of a semiconductor structure 30 in a step of manufacturing thereof, following the step illustrated in FIG. 28, according to one embodiment of present invention. More particularly, embodiments of present invention provide forming conformal dielectric layers 335 covering sidewalls of the recesses 301 and the openings 333. More particularly, the conformal dielectric layers 335, working as protective liners, cover end surfaces of the set of Si nanosheets 211, the inner spacers 324, the sidewall spacers 403, and the sidewalls of the openings 333. The conformal dielectric layers 335 may leave the Si layer 103 at the bottom of the openings 333 exposed for further processing.

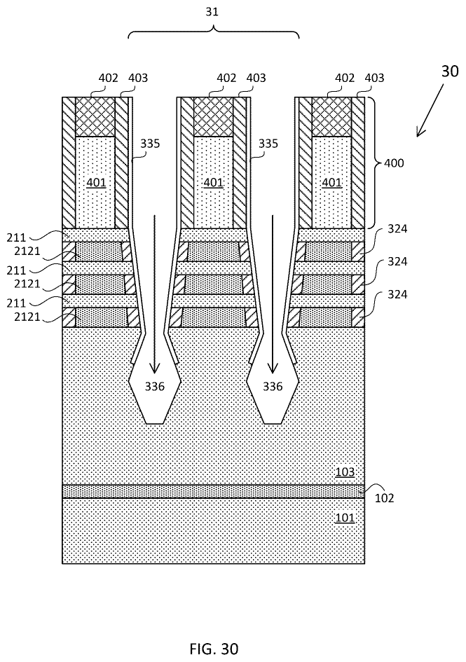

FIG. 30 is a demonstrative illustration of cross-sectional view of a semiconductor structure 30 in a step of manufacturing thereof, following the step illustrated in FIG. 29, according to one embodiment of present invention. More particularly, embodiments of present invention provide selectively etching the Si layer 103 exposed at the bottom of the openings 333 to create cavities 336 in the Si layer 103. The cavities 336 may be created through, for example, a selective RIE process and may be in, when being combined with the openings 333, a diamond shape. The cavities 336 and openings 333, and a portion of recesses 301 above the openings 333, may be later filled with materials, such as epitaxial SiGe, to form placeholders.

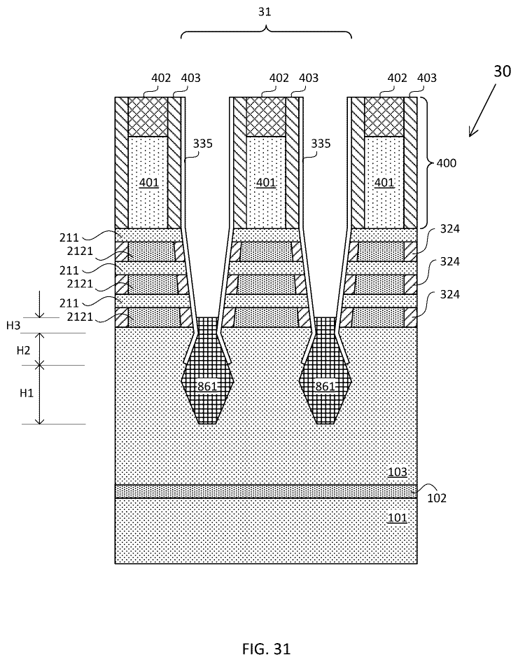

FIG. 31 is a demonstrative illustration of cross-sectional view of a semiconductor structure 30 in a step of manufacturing thereof, following the step illustrated in FIG. 30, according to one embodiment of present invention. More particularly, embodiments of present invention provide epitaxially growing SiGe, for example, in the cavities 336, the openings 333 above the cavities 336, and a lower portion of the recesses 301 to form placeholders 861. For example, SiGe may be epitaxially grown from the Si material of the Si layer 103 at sidewalls of the cavities 336 and continue to grow in the openings 333 surrounded by the conformal dielectric layers 335. The placeholders 861 may be grown to have a top surface that is at or above a top surface of the Si layer 103 of the substrate 100.

As is illustrated in FIG. 31, the placeholders 861 may have a first portion and a second portion above the first portion. The first portion has a height H1 and is directly surrounded by the Si layer 103. The second portion has a bottom section with a height H2 and a top section with a height H3. A vertical cross-section of the top section of the second portion of the placeholders 861 has an inverted trapezoidal shape with a wider base at top and a narrower base at bottom. A vertical cross-section of the bottom section of the second portion of the placeholders 861 has a trapezoidal shape with a narrower base at top and a wider base at bottom. Additionally, the bottom section of the second portion of the placeholders 861 and the first portion of the placeholder 861 together form a diamond shape with multiple facets. Both the top section and the bottom section of the second portion of the placeholders 861 are directly surrounded by the conformal dielectric layers 335.

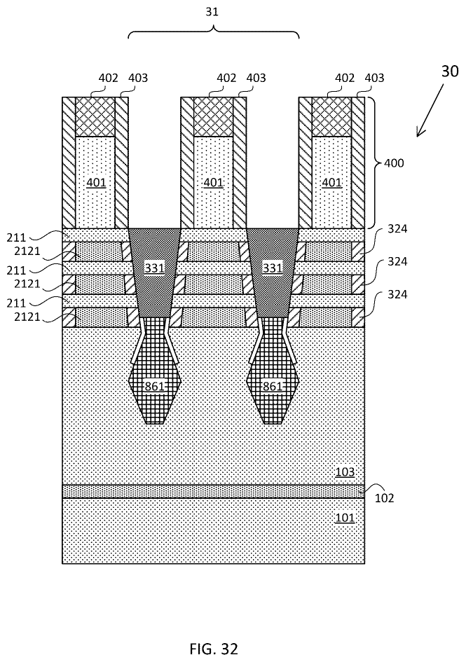

FIG. 32 is a demonstrative illustration of cross-sectional view of a semiconductor structure 30 in a step of manufacturing thereof, following the step illustrated in FIG. 31, according to one embodiment of present invention. More particularly, embodiments of present invention provide selectively removing portions of the conformal dielectric layers 335 above the placeholders 861 to expose end surfaces of the set of Si nanosheets 211. Next, embodiments of present invention provide forming source/drain (S/D) regions 331 of the NS transistor 31 by epitaxially growing P+ Epi SiGe:B or N+ Epi Si:P from exposed end surfaces of the Si nanosheets 211, depending on the type of NS transistor 31 to be formed. Following the shape of the recesses 301, the S/D regions 331 of the NS transistor 31 may have slanted sidewalls and have a wider width at the top and narrower width at the bottom.

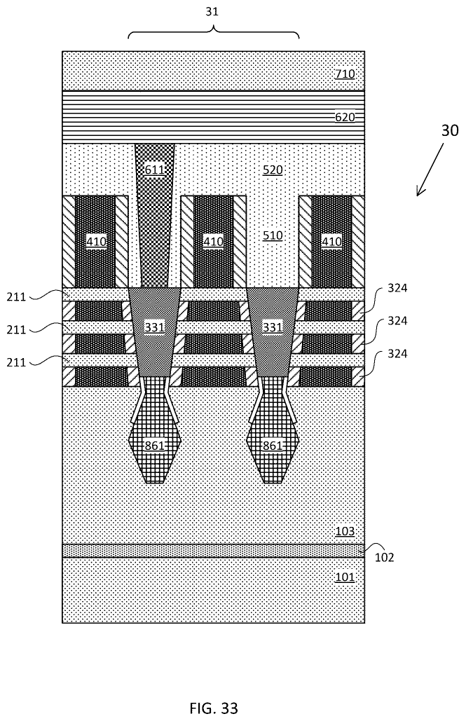

FIG. 33 is a demonstrative illustration of cross-sectional view of a semiconductor structure 30 in a step of manufacturing thereof, following the step illustrated in FIG. 32, according to one embodiment of present invention. More particularly, embodiments of present invention provide performing a RMG process to form a metal gate of the NS transistor 31. In doing so, embodiments of present invention provide covering the S/D regions 331 with a dielectric material thereby forming a dielectric layer 510 on top of the S/D regions 331. Next, the capping layer 402 of the sacrificial gate structures 400 may be removed, for example through a CMP process or a RIE process, to expose the sacrificial gates 401, and remove the exposed sacrificial gates 401. Subsequently, the set of sacrificial sheets 2121 exposed by the removal of the sacrificial gates 401 may be removed thereby exposing a central portion of the set of Si nanosheets 211.

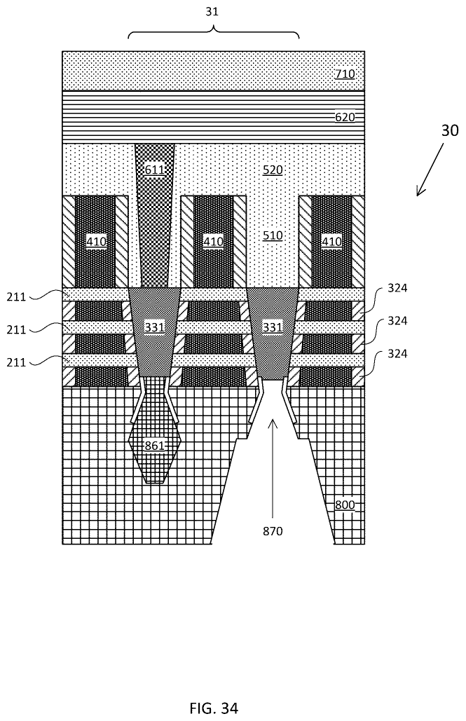

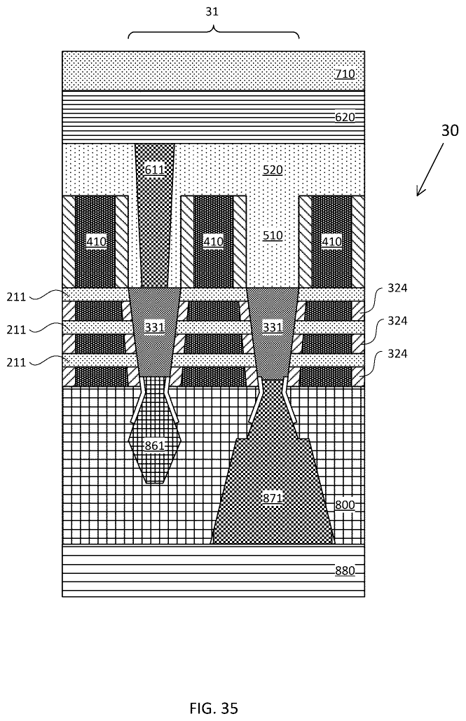

Next, embodiments of present invention provide depositing a gate dielectric layer surrounding the central portions of the set of Si nanosheets 211, depositing one or more work-function metal (WFM) layers on top of the gate dielectric layer, and depositing a conductive material on top of the one or more WFM layers thereby forming a set of metal gates 410. A CMP process may be applied to planarize a top surface of the set of metal gates 410 to be co-planar with the top surface of the dielectric layer 510. Next, additional dielectric materials such as a dielectric layer 520 may be formed, for example through deposition, on top of the set of metal gate 410 and on top of the dielectric layer 510; one or more frontside S/D contacts such as a frontside S/D contact 611 may be formed to be in contact with the S/D region 331; a BEOL interconnect structure 620 may be formed on top of the dielectric layer 520. After forming the BEOL interconnect structure 620, a handling wafer 710 may be attached, for example through a bonding process, to the BEOL interconnect structure 620 such as the semiconductor structure 30 may be flipped upside-down for further processing from the backside of the semiconductor substrate 100. Hereinafter, although various processes may be applied from the backside of the semiconductor structure 30, for the ease of illustration, FIGS. 34-35 will still be demonstratively illustrated upside-up and described according to that illustration FIG. 34 is a demonstrative illustration of cross-sectional view of a semiconductor structure 30 in a step of manufacturing thereof, following the step illustrated in FIG. 33, according to one embodiment of present invention. More particularly, embodiments of present invention provide removing the bulk Si substrate 101; removing the dielectric layer 102 selectively to expose the Si layer 103; and removing the Si layer 103 to expose the placeholders 861. Next, a BILD layer 800 may be deposited to cover the placeholders 861 such that the placeholders 861 may become embedded in the BILD layer 800.

Next, embodiments of present invention provide creating an opening 870 in the BILD layer 800, through a lithographic patterning process, to expose one of the placeholders 861 such as one of the placeholders 861 underneath a first S/D region of the NS transistor 31. Next, the exposed placeholder 861 may be removed through a selective etch process. The selective etch process may remove the placeholder 861, selective to the conformal dielectric layers 335, to expose a bottom surface of the S/D region 331.

FIG. 35 is a demonstrative illustration of cross-sectional view of a semiconductor structure 30 in a step of manufacturing thereof, following the step illustrated in FIG. 34, according to one embodiment of present invention. More particularly, embodiments of present invention provide filling the opening 870 with a conductive material to form a backside contact 871 contacting the S/D region 331 of the NS transistor 31. As is illustrated in FIG. 35, a top section of the backside contact 871, which directly contacts the S/D region 331, may be surrounded by the conformal dielectric layers 335. A CMP process may be applied to planarize a bottom surface of the backside contact 871 to be co-planar with a bottom surface of the BILD layer 800. Next, a backside BEOL interconnect structure 880 may be formed next to the BILD layer 800 and the backside contact 871 to provide signal routing and/or power supply functions to the transistors such as the NS transistor 31.

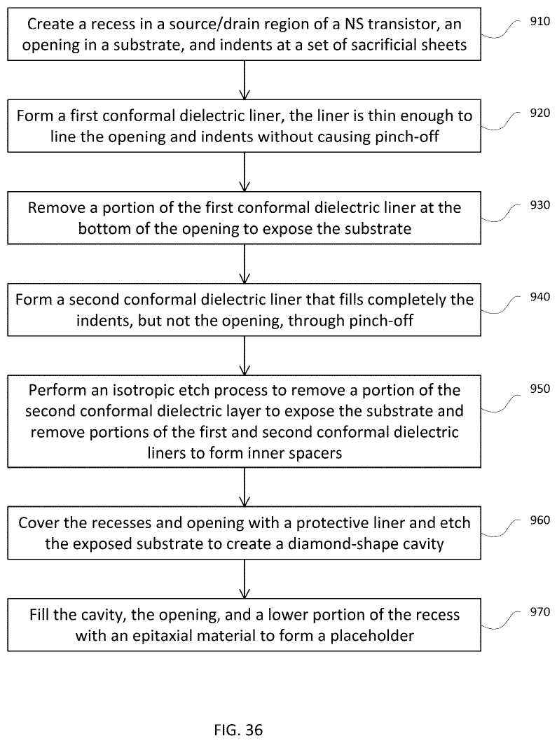

FIG. 36 is a demonstrative illustration of a flow-chart of a method of manufacturing a semiconductor structure according to embodiments of present invention. The method includes (910) creating a recess in a source/drain region of a NS transistor, an opening in a substrate, and indents at a set of sacrificial sheets; (920) forming a first conformal dielectric liner, the liner is thin enough to line the opening and indents without causing pinch-off; (930) removing a portion of the first conformal dielectric liner at the bottom of the opening to expose the substrate; (940) forming a second conformal dielectric liner that fills completely the indents, but not the opening, through pinch-off; (950) performing an isotropic etch process to remove a portion of the second conformal dielectric layer to expose the substrate and remove portions of the first and second conformal dielectric liners to form inner spacers; (960) covering the recesses and opening with a protective liner and etching the exposed substrate to create a diamond-shape cavity; and (970) filling the cavity, the opening, and a lower portion of the recess with an epitaxial material to form a placeholder.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a transistor having a first and a second source/drain (S/D) region;
a backside contact in contact with a bottom surface of the first S/D region; and
a placeholder underneath the second S/D region,
wherein the placeholder includes a first portion and a second portion on top of the first portion; the first portion being embedded in a backside interlevel-dielectric (BILD) layer; the second portion being at least partially surrounded by a dielectric liner; and a top surface of the second portion being above a top surface of the BILD layer.

2. The semiconductor structure of claim 1, wherein the second portion of the placeholder has an inverted trapezoidal shape with a wider base at top and a narrower base at bottom.

3. The semiconductor structure of claim 2, wherein a top section of the second portion of the placeholder is above the top surface of the BILD layer and is surrounded by an airgap, and a bottom section of the second portion of the placeholder is directly surrounded by the dielectric liner.

4. The semiconductor structure of claim 3, wherein a first portion of the backside contact directly contacts the first S/D region and is directly surrounded by the BILD layer.

5. The semiconductor structure of claim 2, wherein the second portion of the placeholder is directly surrounded by the dielectric liner and a top section of the second portion of the placeholder is surrounded by a set of inner spacers via the dielectric liner.

6. The semiconductor structure of claim 1, wherein the second portion of the placeholder has a top section in an inverted trapezoidal shape and a bottom section in a trapezoidal shape, both the top section and the bottom section being directly surrounded by the dielectric layer.

7. The semiconductor structure of claim 6, wherein the first portion of the placeholder and the bottom section of the second portion of the placeholder forms a diamond shape.

8. The semiconductor structure of claim 1, wherein the transistor is a nanosheet transistor having a set of nanosheets including a bottom-most nanosheet, and the top surface of the second portion of the placeholder is at or below the bottom-most nanosheet.

9. A semiconductor structure comprising:
a transistor having a first and a second source/drain (S/D) region;
a backside contact in contact with a bottom surface of the first S/D region; and
a placeholder underneath the second S/D region,
wherein the placeholder includes a first portion and a second portion on top of the first portion, the first portion being embedded in a backside interlevel-dielectric (BILD) layer and the second portion being at least partially surrounded by a dielectric liner and a top surface of the second portion being above a top surface of the BILD layer.

10. The semiconductor structure of claim 9, wherein the second portion of the placeholder is directly surrounded by the dielectric liner and a top section of the second portion of the placeholder is further surrounded by a set of inner spacers via the dielectric liner, the set of inner spacers being above the top surface of the BILD layer.

11. The semiconductor structure of claim 10, wherein the dielectric liner is a first dielectric liner and a first portion of the backside contact directly contacts the first S/D region and is surrounded by a second dielectric liner, wherein the first dielectric liner and the second dielectric liner are made of a same dielectric material.

12. The semiconductor structure of claim 9, wherein the transistor is a nanosheet transistor having a set of nanosheets, and the top surface of the second portion of the placeholder is below the set of nanosheet.

13. The semiconductor structure of claim 9, wherein the second portion of the placeholder has a bottom section and a top section on top of the bottom section with both the bottom section and the top section being directly surrounded by the dielectric liner, a vertical cross-section of the top section having an inverted trapezoidal shape and a vertical cross-section of the bottom section having a trapezoidal shape.

14. The semiconductor structure of claim 13, wherein the first portion of the placeholder is directly surrounded by the BILD layer, the first portion of the placeholder and the bottom section of the second portion of the placeholder forms a diamond shape.

15. The semiconductor structure of claim 14, wherein the bottom section of the second portion of the placeholder is below the top surface of the BILD layer.

16. A semiconductor structure comprising:
a transistor having a first and a second source/drain (S/D) region;
a backside contact in contact with a bottom surface of the first S/D region; and
a placeholder underneath the second S/D region,
wherein the placeholder includes a first portion and a second portion on top of the first portion, the first portion being embedded in a backside interlevel-dielectric (BILD) layer and the second portion being at least partially surrounded by a dielectric liner and a top surface of the second portion being above a top surface of the BILD layer.

17. The semiconductor structure of claim 16, wherein the placeholder is made of epitaxial silicon-germanium; the dielectric liner is made of silicon-nitride; and the BILD layer is made of silicon-oxide.

18. The semiconductor structure of claim 16, wherein the placeholder and the dielectric liner form an airgap surrounding a top section of the second portion of the placeholder.

19. The semiconductor structure of claim 18, wherein the transistor is a nanosheet transistor having a set of nanosheets, and wherein the airgap is below the set of nanosheets and above the BILD layer.

20. The semiconductor structure of claim 18, wherein a top section of the backside contact that directly contacts the first S/D region is surrounded by a set of inner spacers.
